(19) United States
(12) Patent Application Publication
(10) Pub. No.: US 2005/0254432 A1
(43) Pub. Date: Nov. 17, 2005

(54) Measurement of a terminal's receive bit rate

(75) Inventors: Christian Bertin, Rennes (FR); Gilbert Coloigner, Betton (FR)

Correspondence Address: COHEN, PONTANI, LIEBERMAN & PAVANE, Suite 1210, 551 Fifth Avenue, New York, NY, 10176, US

(73) Assignee: France Telecom, Paris (FR)

(21) Appl. No.: 11/083,184

(22) Filed: Mar. 16, 2005

(30) Foreign Application Priority Data
Mar. 18, 2004 (FR) 04 02812

(51) Int. Cl. G01R 31/08

(52) U.S. Cl. 370/241

(57) ABSTRACT

A technique for measuring the receive bit rate available to a client terminal adapted to be connected to a data server via a communications network. The client terminal is connected to a bit rate measuring application host server, a bit rate measuring application is downloaded from the bit rate measuring application host server to the client terminal. The bit rate measuring application is run by connecting the client terminal to a test server, downloading a test file from the test server to the client terminal, and measuring a downloading bit rate for the test file.

### FIELD OF THE INVENTION

The present invention relates generally to measuring the receive bit rate available to a client terminal connected to a communications network and able to download digital data from a data server so that the most appropriate coding bit rate can be selected before sending any data.

### BACKGROUND OF THE INVENTION

Measurement software is already available for installation in the client terminal to periodically measure the quantity of data in transit at a given protocol level and at the access point to the network towards one or more equipment units connected to the network. This software is independent of the equipment that generates the data traffic. It is therefore not adapted to measure a terminal's receive bit rate. It provides statistical results relating to the network and intended for the network operator but not for a data server.

Measuring software is also already available for installation at the server end of the connection to measure the quantity of data in transit at a given protocol level and at the access point to the network towards a client terminal.

The documents U.S. 2002/0044528, U.S. 2002/0165970 and EP 0 622 967 relate to measurements carried out at the server end, for example.

That type of architecture has drawbacks. The bit rate is measured by a given server, for the specific requirements of that server. It is therefore necessary to repeat the measurement for each server. Also, the server must use a traffic generator coupled to a traffic absorber application in the client terminal.

Furthermore, it must be possible to measure the bit rate rapidly.

### OBJECTS AND SUMMARY OF THE INVENTION

One object of the present invention is to provide a method and a system for rapid measurement of the receive bit rate available to a client terminal connected to a communications network and able to download digital data from a data server.

This and other objects are attained in accordance with one aspect of the present invention directed to a method of measuring the receive bit rate available to a client terminal adapted to be connected to a data server via a communications network. The client terminal is connected to a bit rate measuring application host server. A bit rate measuring application is downloaded from the bit rate measuring application host server to the client terminal. The bit rate measuring application is run by connecting the client terminal to a test server, downloading a test file from the test server to the client terminal, and measuring a downloading bit rate for the test file.

The receive bit rate available to a client terminal can be measured independently of receiving digital data from the data server and with no link to a specific server.

According to a preferred feature, the test file contains packets of data and the step of measuring the test file downloading bit rate comprises measuring a downloading bit rate after the reception of each packet, performing a measured bit rate stability test, and halting the downloading of the test file and the measurement if the stability test is satisfied.

The bit rate is therefore measured rapidly.

According to a preferred feature, a downloading bit rate is measured after the reception of each packet between a packet of predetermined order in the test file and the latest packet received.

The measurement results tend rapidly towards a stable value.

To be more precise, a downloading bit rate is measured after the reception of each packet between the end of reception of the first packet in the test file and the end of reception of the latest packet received.

Alternatively, a downloading bit rate is measured after the reception of each packet over a predetermined number of latest packets received.

According to a preferred feature, the stability criterion is satisfied if the difference between the measured bit rates on the reception of two consecutive packets over a predetermined range of packets is below a predetermined threshold.

This criterion is simple to apply and to monitor.

Another feature of the invention is directed to a method of downloading digital data to a client terminal adapted to be connected to a server via a communications network, which method comprises the available bit rate measuring method as defined above and then a step of connecting the client terminal to the data server with an indication depending on the measured available bit rate.

A feature of the invention further provides a method of downloading digital data to a client terminal adapted to be connected to a server via a communications network, which method comprises the available bit rate measuring method as defined above, a preliminary step of requesting downloading of specific data, and a subsequent step of connecting the client terminal to the data server with an address determined as a function of the measured available bit rate.

Another aspect of the invention is directed to a bit rate measuring system comprising means for implementing the above method.

The downloading method and the bit rate measuring system have advantages similar to those described above.

### BRIEF DESCRIPTION OF THE DRAWINGS

FIG. 1 shows one embodiment of a system of the invention,

FIG. 2 shows a first embodiment of a system of the invention,

FIG. 3 shows one embodiment of a bit rate measuring method of the invention,

FIG. 4 shows a second embodiment of a system of the invention, and

FIG. 5 shows how bit rate is measured.

### DETAILED DESCRIPTION OF THE DRAWINGS

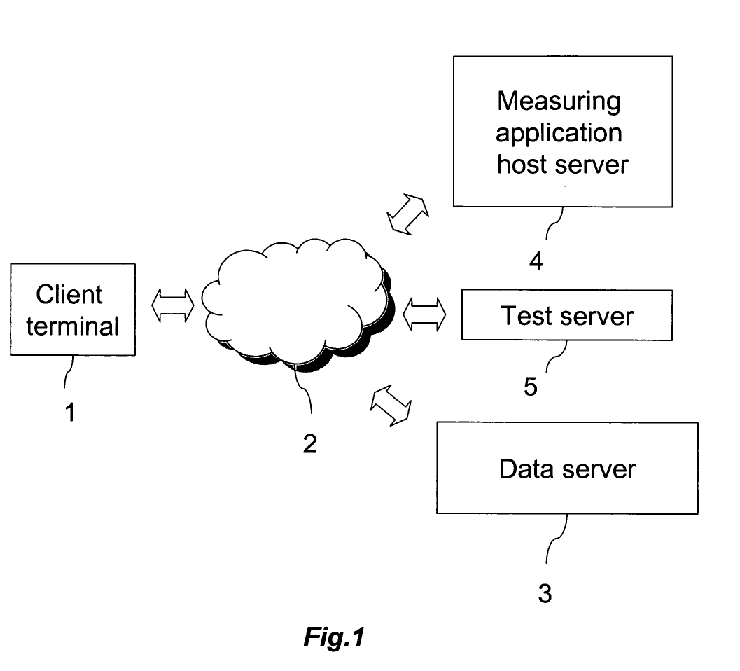

In an embodiment of the invention shown in FIG. 1, the system comprises a client terminal 1 connected to a communications network 2 to which a data server 3 is also connected. For example, the data server 3 is adapted to supply data at bit rates in a range of different predetermined bit rates using a continuous transmission technique known as streaming.

The data is supplied to the client terminal 1 at a bit rate that must in particular be adapted to the maximum bit rate that the terminal 1 is able to receive.

According to the invention, a bit rate measuring application host server 4 and a test server 5 are connected to the communications network 2.

The system for measuring the receive bit rate available to the client terminal 1 adapted to be connected to the data server via a communications network comprises:
means for connecting the client terminal 1 to the bit rate measuring application host server 4,
means for downloading a bit rate measuring application from the bit rate measuring application host server to the client terminal,
means for running the bit rate measuring application, which comprises the steps of:
connecting the client terminal 1 to the test server 5,
downloading a test file from the test server to the client terminal, and
measuring a downloading bit rate for the test file.

The functioning of the servers 4 and 5 is explained below. Note that the servers 4 and 5 may be physically combined into a single server. Also, the servers 4 and 5 may be combined with the data server 3.

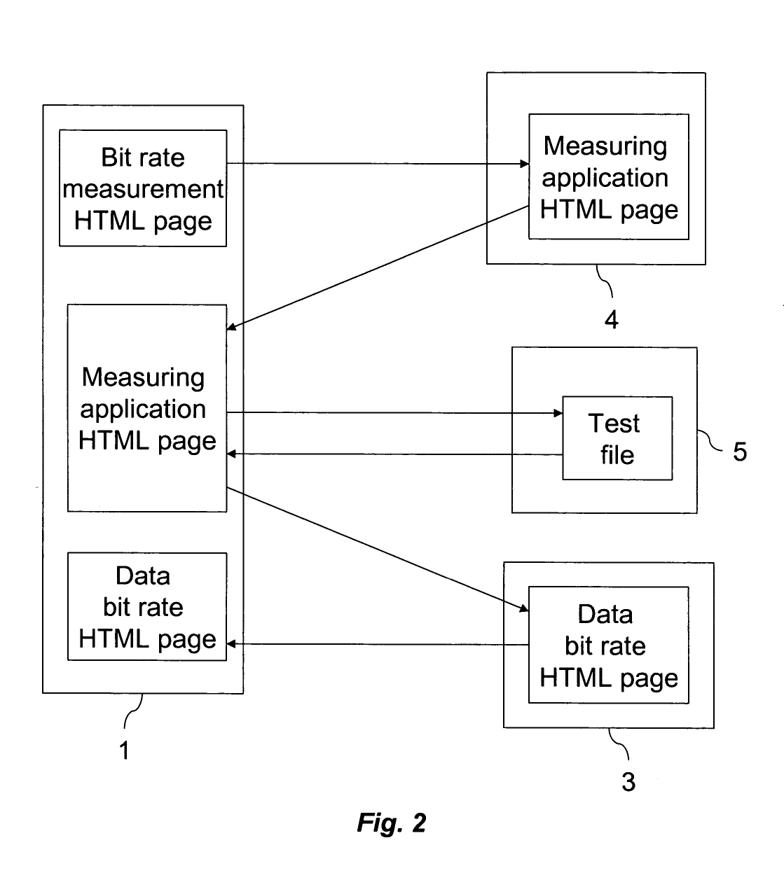

FIG. 2 shows how the components from FIG. 1 interact in a first embodiment of the invention.

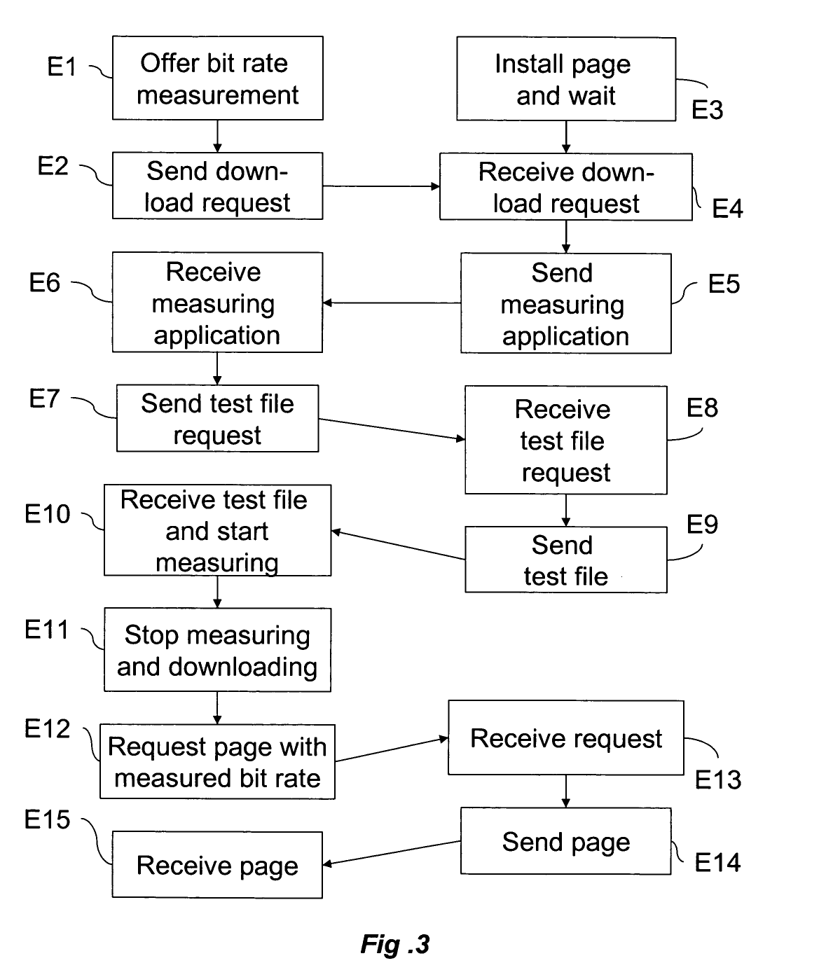

FIG. 3 represents a corresponding bit rate measuring method in the form of an algorithm comprising steps E1 to E15.

The step E1 displays on the client terminal an HTML page that offers measurement of the effective receive bit rate for the client terminal 1. It is assumed below that the user requests this bit rate measurement.

The next step E2 sends a request to download a bit rate measuring application in the form of an HTML page from the client terminal 1 to the application host server 4.

The step E3 installs the HTML page containing the bit rate measurement application in the dedicated server 4 and awaits a request to download the bit rate measuring application.

In the next step E4 the server 4 receives from the client terminal 1 a request to download the bit rate measuring application.

In the next step E5 the server 4 sends the HTML page containing the bit rate measuring application to the client terminal 1.

In the step E6 the client terminal 1 receives this page.

In the next step E7 the client terminal 1 sends a test file request to the test server 5.

In the step E8 the test server 5, which has until this point been in a waiting state, receives the test file request.

In the next step E9 the server 5 sends the test file to the client terminal 1. The test file contains data that is transmitted in the form of packets of data. The transmission comprises 50 packets each of 4000 bytes, for example.

In the step E10 the client terminal receives the test file progressively and at the same time measures the available receive bit rate.

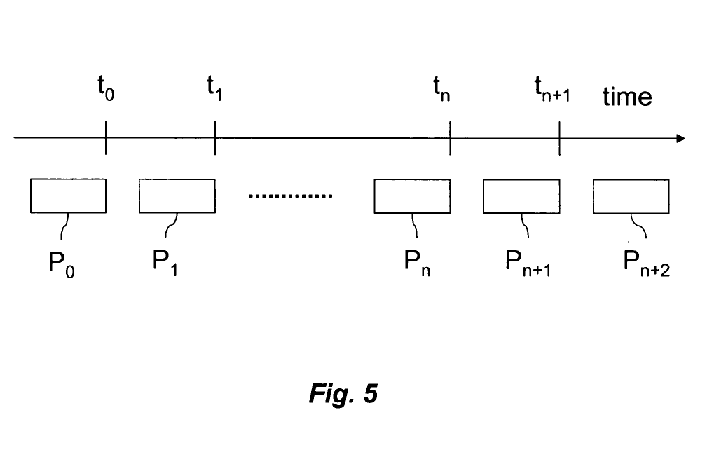

The measurement is effected in the manner shown in FIG. 5 using the times at which the reception of packets ends. At the end of reception of the first packet P₀ the received byte count is initialized and the receive times are initialized to a time t₀. This means that the content of the first packet is ignored.

A count showing the total number of bytes received since the initial time t₀ is available at the end of reception of each packet Pₙ. The bit rate is the ratio of this count to the difference between the current time tₙ and the initial time t₀.

Alternatively, the bit rate is calculated over a predetermined number of the latest packets received.

Test file packets are received and the bit rate is measured until the measurement result stabilizes. The stability criterion is satisfied when the absolute value of the difference between the measured bit rates on reception of two consecutive packets over a predetermined range of packets is below a predetermined threshold, for example 2%.

If the stability criterion is satisfied, the bit rate measurement ends. The last value measured is the receive bit rate available to the client terminal 1.

The step E10 is then followed by the step E11 in which the measurement terminates and the downloading of the test file stops.

In the next step E12 the client terminal 1 requests from the data server 3 a PHP page with the measured bit rate as a parameter.

In one particular embodiment, the PHP page request is sent to an intermediate server.

Alternatively, instead of the measured bit rate, a bit rate plateau value compatible with the measured bit rate is integrated into the request. In this case, the possible bit rate values are downloaded beforehand, for example at the same time as the bit rate measuring application.

The data server 3 contains data, for example an audiovisual content, available at different bit rates and in the form of different files each corresponding to a given bit rate.

In the step E13 the server 3, or the intermediate server, receives the PHP page request accompanied by the receive bit rate available at the client terminal or the bit rate plateau value. The server 3, or the intermediate server, creates an HTML page indicating a preferred bit rate for sending data. The preferred bit rate depends on the measured bit rate.

In the next step E14 the data server 3 or the intermediate server sends the HTML page created in the preceding step to the client terminal 1.

For example, if the measured bit rate is from 0 to 48 kbit/s, the server sends an HTML page indicating that, at that bit rate, the requested data cannot be sent.

If the measured bit rate is from 48 to 120 kbit/s, the server sends an HTML page indicating that the most suitable bit rate for sending the requested data is 40 kbit/s.

If the measured bit rate is from 120 to 360 kbit/s, the server sends an HTML page indicating that the most suitable bit rate for sending the requested data is 100 kbit/s.

If the measured bit rate is from 360 to 840 kbit/s, the server sends an HTML page indicating that the most suitable bit rate for sending the requested data is 300 kbit/s.

If the measured bit rate is greater than 840 kbit/s, the server sends an HTML page indicating that the most suitable bit rate for sending the requested data is 700 kbit/s.

In the step E15 the client terminal 1 receives and displays the HTML page sent by the data server 3 or the intermediate server.

The client terminal can then request the data server 3 to download the data at the most suitable bit rate available to the user.

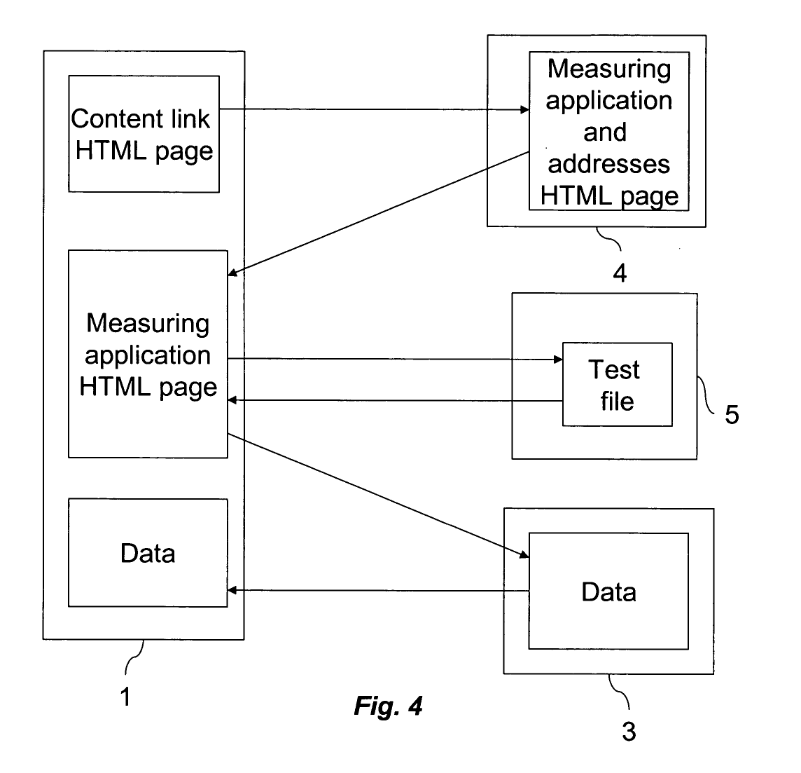

FIG. 4 shows a second embodiment in which the bit rate measurement request is made at the same time as a request to download data. Bit rate measurement may even be requested in a manner that is transparent for the user.

This embodiment functions in a similar way to the prior embodiment, except in the following respects:

When the bit rate measurement application is downloaded to the client terminal, it is accompanied by a set of addresses. Each address corresponds to the data at a particular bit rate.

When the available bit rate has been measured, the client terminal requests the data at the available bit rate directly, by means of its address.

Of course, variants of the above are feasible. In particular, when the available bit rate has been measured, it is possible to offer the client terminal user a plurality of downloading bit rate values determined as a function of and compatible with the measured bit rate. The user may then select a bit rate value, which is then substituted for the measured bit rate value. In particular, it is the selected value that is used to download the data.

1. A method of measuring the receive bit rate available to a client terminal adapted to be connected to a data server via a communications network, which method comprises the steps of:
connecting the client terminal to a bit rate measuring application host server,
downloading a bit rate measuring application from the bit rate measuring application host server to the client terminal,
running the bit rate measuring application, which comprises the steps of:
connecting the client terminal to a test server,
downloading a test file from the test server to the client terminal, and
measuring a downloading bit rate for the test file.

2. An available bit rate measuring method according to claim 1, wherein the test file contains packets of data and the step of measuring the test file downloading bit rate comprises:
measuring a downloading bit rate after the reception of each packet,
performing a measured bit rate stability test, and
halting the downloading of the test file and the measurement if the stability test is satisfied.

3. An available bit rate measuring method according to claim 2, wherein a downloading bit rate is measured after the reception of each packet between a packet of predetermined order in the test file and the latest packet received.

4. An available bit rate measuring method according to claim 2, wherein a downloading bit rate is measured after the reception of each packet between the end of reception of the first packet in the test file and the end of reception of the latest packet received.

5. An available bit rate measuring method according to claim 2, wherein a downloading bit rate is measured after the reception of each packet over a predetermined number of latest packets received.

6. An available bit rate measuring method according to claim 2, wherein the stability criterion is satisfied if the difference between the measured bit rates on the reception of two consecutive packets over a predetermined range of packets is below a predetermined threshold.

7. A method of downloading digital data to a client terminal adapted to be connected to a server via a communications network, which method comprises the available bit rate measuring method according to claim 1, and then a step of connecting the client terminal to the data server with an indication depending on the measured available bit rate.

8. A method of downloading digital data to a client terminal adapted to be connected to a server via a communications network, which method comprises the available bit rate measuring method according to claim 1, a preliminary step of requesting downloading of specific data, and a subsequent step of connecting the client terminal to the data server with an address determined as a function of the measured available bit rate.

9. A system for measuring the receive bit rate available to a client terminal adapted to be connected to a data server via a communications network, which system comprises:
means for connecting the client terminal to a bit rate measuring application host server,
means for downloading a bit rate measuring application from the bit rate measuring application host server to the client terminal,
means for running the bit rate measuring application, for:
connecting the client terminal to a test server,
downloading a test file from the test server to the client terminal, and
measuring a downloading bit rate for the test file.

10. A bit rate measurement application host server adapted to hose a bit rate measurement application comprising the steps of:
connecting the client terminal to a test server,
downloading a test file from the test server to the client terminal, and
measuring a downloading bit rate for the test file,
the server also being adapted to download that application to a client terminal via a communications network.

11. A computer program stored on an information medium and comprising instructions for executing the method according to claim 1.
